(19) United States
(12) Patent Application Publication
(10) Pub. No.: US 2026/0313833 A1
(43) Pub. Date: Oct. 8, 2026

(54) BIDIRECTIONAL THERMAL DISSIPATION FOR ENHANCED SYSTEM MANAGEMENT

(71) Applicant: Dell Products L.P., Round Rock, TX (US)

(72) Inventors: WEIDONG ZUO, Shrewsbury, MA (US); WUCK FOO WONG, Linkou Dist (TW); SHIH-HUAI CHO, Hopkinton, MA (US)

(21) Appl. No.: 19/169,667

(22) Filed: Apr. 3, 2025

(51) Int. Cl. H05K 7/20

(52) U.S. Cl. CPC H05K 7/20272; H05K 7/20772

(57) ABSTRACT

Methods, systems, and devices are provided for thermal management of data processing systems. Such systems may include heat generating components, liquid cooling systems to cool the heat generating components, and a thermal dissipator to dissipate heat from the liquid cooling system. To do so, the thermal dissipator may include a first set of radiators; a second set of radiators; and manifolds that distribute a first portion of a hot fluid to the first set of radiators; and a second portion of the hot fluid to the second set of radiators. a first flow of the first portion of the hot liquid in the first set of radiators is established in a first direction; and a second flow of the second portion of the hot liquid in the second set of radiators is established in a second direction that is different from the first direction.

### FIELD

Embodiments disclosed herein relate (generally) to thermal management of data processing systems. More particularly, embodiments disclosed herein relate to systems and methods for mitigating (e.g., heat) damage to data processing systems.

### BACKGROUND

Computing devices may provide computer-implemented services. The computer-implemented services may be used by users of the computing devices and/or devices operably connected to the computing devices. The computer-implemented services may be performed with hardware components such as processors, memory modules, storage devices, and communication devices. The operation of these components and the components of other devices may impact the performance of the computer-implemented services.

### BRIEF DESCRIPTION OF THE DRAWINGS

Embodiments disclosed herein are illustrated by way of example and not limitation in the figures of the accompanying drawings in which like references indicate similar elements.

FIGS. 1-2 show diagrams illustrating a data processing system in accordance with an embodiment.

FIG. 3 shows a diagram illustrating a thermal dissipator in accordance with an embodiment.

FIG. 4 shows a block diagram illustrating a data processing system in accordance with an embodiment.

### DETAILED DESCRIPTION

Various embodiments will be described with reference to details discussed below, and the accompanying drawings will illustrate the various embodiments. The following description and drawings are illustrative and are not to be construed as limiting. Numerous specific details are described to provide a thorough understanding of various embodiments. However, in certain instances, well-known or conventional details are not described in order to provide a concise discussion of embodiments disclosed herein.

Reference in the specification to “one embodiment” or “an embodiment” means that a particular feature, structure, or characteristic described in conjunction with the embodiment can be included in at least one embodiment. The appearances of the phrases “in one embodiment” and “an embodiment” in various places in the specification do not necessarily all refer to the same embodiment.

References to an “operable connection” or “operably connected” means that a particular device is able to communicate with one or more other devices. The devices themselves may be directly connected to one another or may be indirectly connected to one another through any number of intermediary de vices, such as in a network topology.

In general, embodiments disclosed herein relate to methods and systems for managing a data processing system. The data processing system may provide computer-implemented services. To provide the computer-implemented services, the data processing system may need to operate in operable conditions. These operable conditions may be predetermined operating conditions in which the data processing system is known to operates optimally (e.g., an optimal thermal range within which a data processing system’s operation may result in the computer-implemented services being provided as expected and/or desired by a consumer of such services).

To place the data processing system in the operable conditions, the data processing system may include, and/or accommodate the installation of, a liquid cooling system. The liquid cooling system may place the data processing system in the operable conditions by providing a means for regulating heat that is generated by hardware components of the data processing system. For example, heat may be generated by the hardware components while the hardware components process workloads and/or otherwise facilitate functionalities of the data processing system that permit the data processing system to provide the computer-implemented services.

If the generated heat is not properly regulated (e.g., by way of dissipation), the hardware components may be damaged by the generated heat as more heat is continuously generated during the data processing system’s operation, and may therefore result in a buildup of heat that is beyond the thermal range for optimal operation of the data processing system. Consequently, this buildup of heat may result in the hardware components being damaged.

Consequently, damage to the hardware components may cause workloads performed by the hardware components and/or facilitated functionalities of the data processing system to be lost (referred to as “workload loss”) and/or otherwise deprecated (resulting in less-than-optimal operation of the data processing system at best).

Such loss and/or deprecation may, in turn, negatively impact (e.g., delay and/or prevent entirely) the data processing system’s providing of the computer-implemented services. Therefore, sufficient thermal regulation (e.g., by way of a rate of dissipation deemed sufficient for preventing such a deprecating buildup of heat) may be attempted as discussed below.

To increase the likelihood of placing the data processing system in the operable conditions (therefore increasing a likelihood of the computer implemented services being provided as expected and/or desired by a consumer of such services), the liquid cooling system may include, and/or accommodate the installation of, a bidirectional thermal dissipator.

This bidirectional thermal dissipator, along with the rest of the liquid cooling system may place the data processing system in the operable conditions by providing a means for regulating heat that may be generated by hardware components of the data processing system. By doing so, embodiments disclosed herein may reduce the likelihood of such aforementioned services being negatively impacted (e.g., delayed and/or prevented entirely).

In an embodiment, a data processing system for providing computer-implemented services using, at least in part, a heat generating component is provided. The data processing system may include: the heat generating component; a liquid cooling system to cool the heat generating component; and a thermal dissipator to dissipate heat in the liquid cooling system, the thermal dissipator including a first set of radiators; a second set of radiators; and a set of manifolds adapted to: distribute a first portion of a hot fluid to the first set of radiators; distribute a second portion of the hot fluid to the second set of radiators; establish a first flow of the first portion of the hot fluid in the first set of radiators in a first direction; and establish a second flow of the second portion of the hot fluid in the second set of radiators in a second direction that is different from the first direction.

The first set of radiators and the second set of radiators may be aligned.

The first set of radiators and the second set of radiators may be interleaved.

A radiator of the first set of radiators may include: a fluid receiving port; a fluid exhaust port; and a surface adapted to exhaust heat into an ambient environment.

The radiator may further include a fluid conduit between the fluid receiving port and the fluid exhaust port to enable the hot fluid to traverse proximate to the surface.

The set of the manifolds may include a first pair of the manifolds attached to the first set of radiators; and a second pair of the manifolds attached to the second set of radiators.

The thermal dissipator may further include a fluid divider to divide the hot fluid into the first portion of the hot fluid and the second portion of the hot fluid.

The fluid divider may include a hot fluid receiving port; and at least two hot fluid exhaust ports to flow the first portion of the hot fluid to the first pair of the manifolds and flow the second portion of the hot fluid to the second pair of the manifolds.

The thermal dissipator may further include a fluid combiner to combine a first portion of cooled fluid and a second portion of the cooled fluid.

The fluid combiner may include a cooled fluid exhaust port; and at least two cooled fluid receiving ports to flow the first portion of the cooled fluid from the first pair of the manifolds and flow the second portion of the cooled fluid from the second pair of the manifolds.

While the first portion of the hot fluid traverses the first set of radiators, a first thermal profile across the first set of radiators may be established.

While the second portion of the hot fluid traverses the second set of radiators, a second thermal profile across the second set of radiators may be established.

The first thermal profile may be inverse to the second thermal profile.

The data processing system may further include a chassis for housing the heat generating component, wherein the liquid cooling system may traverse a boundary of the chassis to facilitate flow of the hot fluid from the heat generating component to the thermal dissipator.

In an embodiment, a liquid cooled chassis for thermal management of data processing systems is provided.

In an embodiment, a rack system for managing (e.g., thermally) data processing systems is provided.

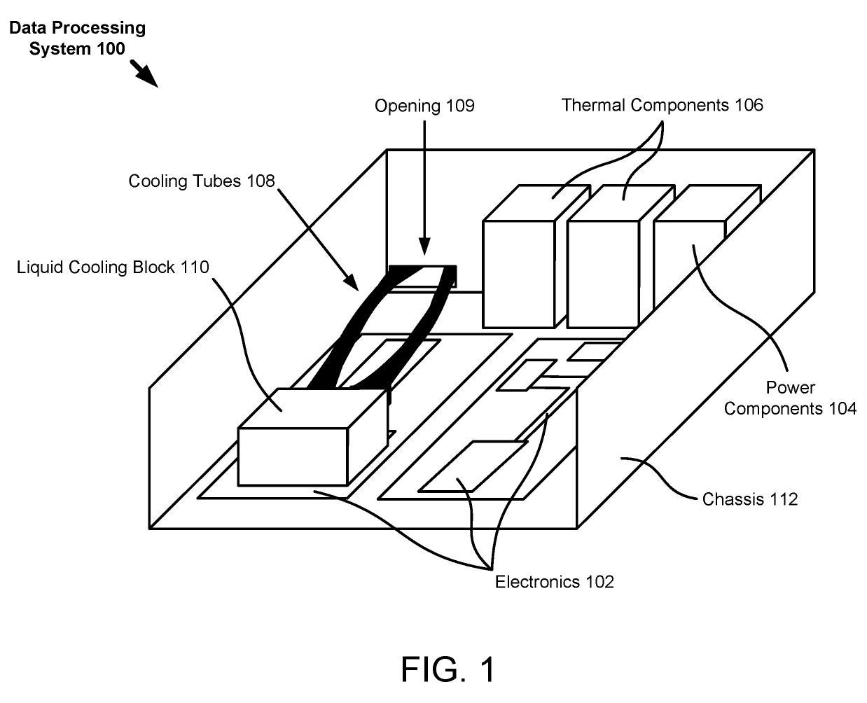

Turning to FIG. 1, a block diagram illustrating a data processing system (e.g., 100) in accordance with an embodiment is shown. The data processing system shown in FIG. 1 may provide computer implemented services, as discussed below.

The computer implemented services may include any type and quantity of computer implemented services. The computer implemented services may include, for example, database services, data processing services, electronic communication services, and/or any other services that may be provided using one or more computing devices. The computer implemented services may be provided by, for example, any portion of data processing system 100, and/or any other type of devices not to be limited by embodiments discussed herein.

Other types of computer implemented services may be provided by the system shown in FIG. 1 without departing from embodiments disclosed herein.

To provide the computer implemented services, data processing systems may include any number of hardware components. For example, operation of the any number of hardware components may facilitate various functionalities of a data processing system, thereby causing the data processing system to provide the computer implemented services. For example, to facilitate the various functionalities, a hardware component may transmit data to and/or from other devices via various avenues of communication. For example, such avenues of communication may depend on physical operable connections that directly connect multiple hardware components to one another.

However, such hardware components may generate heat while facilitating any number of the functionalities as a byproduct of those functionalities. Consequently, if such heat is not properly regulated (e.g., dissipated) to remain within an operational threshold (e.g., a thermal range) of the data processing system, the computer implemented services may be negatively impacted (e.g., may be delayed and/or prevented entirely). For example, excessive heat may physically damage the hardware components.

To improve the likelihood of providing the computer implemented services as expected and/or desired by a consumer of such services, a combination of liquid and air heat transport/dissipation may be utilized. For example, the data processing system may have a liquid cooling system equipped to a chassis that houses the hardware components for the data processing system. This liquid cooling system may facilitate traversal of a (cooling) fluid, for example, within a boundary of the chassis, the traversal running proximate to the hardware components, and the fluid’s proximate traversal to the hardware components causing a transference of the heat generated by the hardware components to the fluid. By doing so, the now-heated fluid may continue to flow through the liquid cooling system and have the transferred heat be dissipated by any number of means (e.g., by an airflow occurring proximate to the heated fluid), the heat being dissipated away from the hardware components (and therefore, the data processing system) and such dissipation of the heat resulting in the fluid being cooled (e.g., the ‘now-cooled’ fluid).

Additionally, it will be appreciated then that such dissipation may be based on a thermal delta of two or more mediums between which the heat may be transferred. For example, the speed and/or efficiency of the heat dissipation from the fluid to air flowing proximate to the fluid throughout an ambient environment may be based on a thermal gradient (e.g., delta) between the fluid and the air, the greater the gradient, the greater the speed and/or efficiency of heat transference.

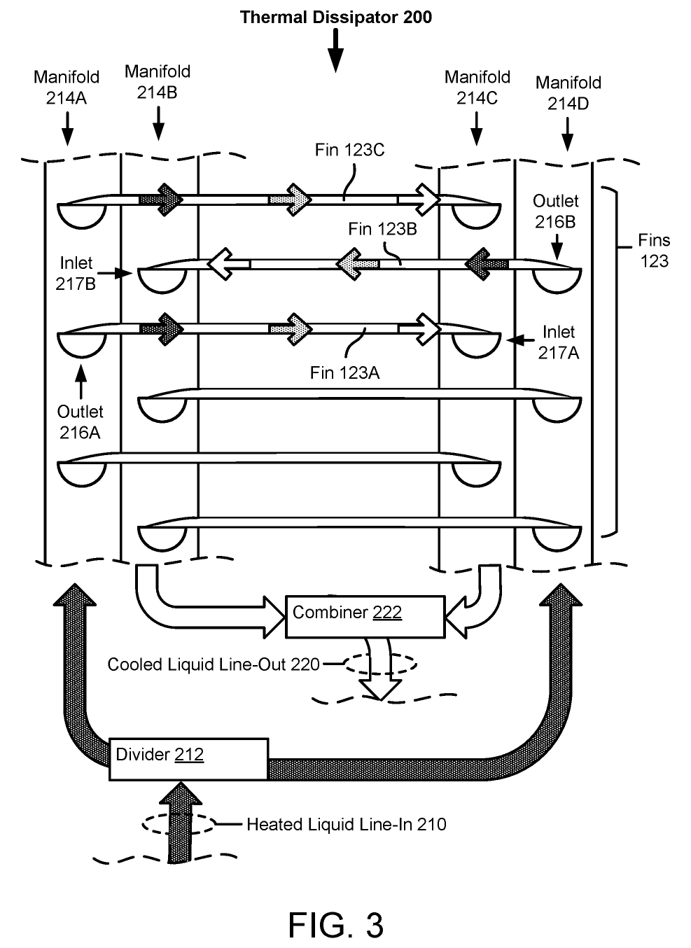

Therefore, to increase the likelihood of providing the computer implemented services as expected and/or required by a consumer of such services, a rate of dissipation may be improved by enhancing and/or otherwise increasing the thermal delta between, for example, the fluid and the air. To do so, alternating flow paths (e.g., as the fluid is directed throughout portions of a radiator, the portions including the flow paths that may be alternating in respective orientations with respect to one another) may be utilized to dissipate heat from the fluid, the alternating flow paths allowing the thermal delta to be increased (e.g., discussed further with regard to FIG. 3. Consequently, this use of alternating flow paths may result in enhanced cooling for the data processing system compared to management of the system when the alternating flow paths are not utilized.

To provide the above noted functionality, the system of FIG. 1 may include data processing system 100. Data processing system 100 may include electronics 102, chassis 112, power components 104, and thermal components 106. Each of these is discussed below.

Electronics 102 may include at least a portion of the any number of hardware components, and as noted above, may provide computer implemented services. Hardware components of electronics 102 may be positioned on circuit cards and may generate heat while operating. These circuit cards may be pieces of circuit boards, for example.

Electronics 102 and/or any other components of the any number of hardware components of data processing system 100 may be positioned in chassis 112 (e.g., housed in chassis 112). Chassis 112 may include an enclosure in which physical structures of electronics 102 (e.g., processors, memory, etc.), and/or other components of data processing system 100 may be positioned. For example, chassis 112 may facilitate placement and management of electronics 102 and/or other components (e.g., power components 104 and/or thermal components 106) in computing environments such as those discussed herein, chassis 112 being implemented by, for example, a rack mount frame of a rack mount chassis system.

Power components 104 may power the any number of hardware components of data processing system 100 (e.g., electronics 102). In some cases, for example, power components 104 may be implemented using power supplies. In other cases, for example, power components may be implemented using power rails and/or other types of operable connections that receive/distribute power provided by a busbar that distributes power throughout a rack system with which any number of data processing systems may be positioned, the power being provided to the busbar by power supplies, for example.

Furthermore, operation of these power supplies and any other power components may also contribute to the generation of heat. If left unregulated, this generation of heat may increase a likelihood of negatively impacting the components, and therefore, the providing of the computer implemented services by said components.

To manage the heat, data processing system 100 may include thermal components 106. Thermal components 106 may thermally manage any of the components of data processing system 100 (e.g., electronics 102 and/or power components 104). For example, thermal components 106 may include components such as cooling fans, coolant reservoirs, receiving elements for coolant, coolant (e.g., the fluid), circulation pumps, manifolds or other types of flow control components, and/or other components to facilitate performance of liquid and/or air -based cooling of at least some of electronics 102. For example, thermal components 106 may be used with cooling tubes 108 and liquid cooling block 110, each of which is discussed below.

Liquid cooling block 110 may facilitate a dissipation of heat generated by, for example, electronics 102 by circulating the cooling fluid via cooling tubes 108. To provide its functionality, liquid cooling block 110 may operate similarly to a heat sink for some electronic components (e.g., a central processing unit (CPU) of the data processing system). For example, liquid cooling block 110 may be placed with an electronic component to (i) receive heat generated by the electronic component, and (ii) dissipate the received heat into the cooling fluid circulated through liquid cooling block 110. While providing its functionality, a transference of at least a portion of the generated heat may be facilitated.

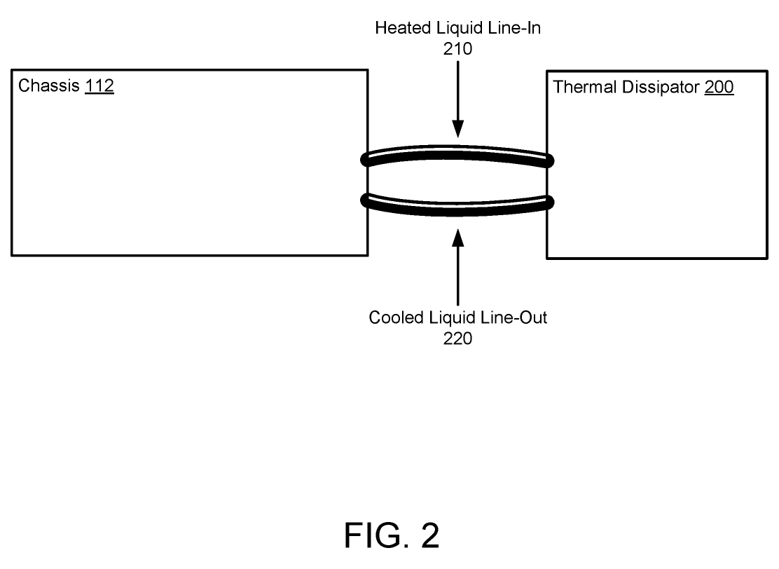

For example, the fluid may be confined to a flow path that circulates through a loop of a liquid cooling system (e.g., cooling tubes 108, liquid cooling block 110, external components such as large-scale coolant chillers, flow controllers, a thermal dissipator (discussed further with regard to FIGS. 2 and 3), etc.), may be placed in thermal communication with a hardware component of electronics 102 that is and/or has been generating heat when the fluid is flowing through a portion of the loop that is proximate to the hardware component. By being in this thermal communication, the fluid may be heated while the heat generated by the hardware component is dissipated into the (e.g., ‘now-heated’) fluid, thereby regulating the temperature of the hardware component.

Due to the now-heated fluid circulating through liquid cooling block 110, this now-heated fluid may flow to another portion of the loop (e.g., external to data processing system 100 such as a large-scale chiller/radiator (e.g., a thermal dissipator discussed further below). For example, the now-heated fluid may flow through cooling tubes 108, through opening 109 (an opening, gap, hole, etc. in the enclosure that is chassis 112) and continue to flow to a radiator, discussed further below with regard to FIG. 2, where the heat may be dissipated from the fluid and into air flowing throughout an ambient environment of the radiator/data processing system 100 to cool the fluid. The (e.g., ‘now-cooled’) fluid may then be redirected toward the hardware component through opening 109 via cooling tubes 108’s restriction of the cooling fluid’s flow path, and towards liquid cooling block 110. In doing so, for example, the cooling fluid may be looped through the liquid cooling system to facilitate this heat transference/dissipation process any number of times.

It will be appreciated that although discussed with regard to a looped flow path of the liquid cooling system, a flow path of a portion the liquid cooling system housed by chassis 112 may include any shape/structure of flow path not to be limited by embodiments discussed herein.

Thus, the cooling liquid may be cyclically heated and cooled as the cooling fluid continues to traverse the flow path, thereby contributing to the dissipation of heat generated by the any number of hardware components (e.g., of electronics 102). For example, the fluid may be directed through an interior of liquid cooling block 110 and through a first portion of cooling tubes 108. Cooling tubes 108 may further facilitate the circulation by directing the fluid, for example, to other cooling blocks proximate to other hardware components of electronics 102 to facilitate cooling of multiple hardware components of electronics 102. To do so, cooling tubes 108 may include hollow, tubular structures in which liquid may flow through. For example, the fluid, once cooled by external chillers/radiators (e.g., the now-cooled fluid), may then be further circulated through a second portion of cooling tubes 108 to direct the fluid back into chassis 112 (e.g., via opening 109), and then into/through liquid cooling block 110 to facilitate transference of additional heat generated by electronics 102 (e.g., generated by the CPU).

While illustrated in FIG. 1 with a limited number of specific components, a system may include additional, fewer, and/or different components without departing from embodiments disclosed herein.

To further clarify embodiments disclosed herein, diagrams illustrating a data processing system (and/or portions thereof) in accordance with embodiments are shown and discussed with regard to FIGS. 2-3. Furthermore, diagrams illustrating examples of a thermal dissipator in accordance with embodiments are shown and discussed further below with regard to FIGS. 2-3 as well.

Turning to FIG. 2, a diagram illustrating a data processing system (e.g., 100) in accordance with an embodiment is shown. The data processing system shown in FIG. 2 may provide computer implemented services, as previously discussed, as well as discussed further below.

As discussed with regard to FIG. 1, chassis 112 may be implemented by an enclosure to house the hardware components, the enclosure being, for example, a rack mount frame or a similarly capable housing structure.

Cooling tubes 108 (depicted in FIG. 1) may direct the fluid through opening 109 (also depicted in FIG. 1) and toward, for example, a device such as a radiator positioned outside of chassis 112’s interior as shown in FIG. 2 by thermal dissipator 200. Therefore, it will be appreciated that cooling tubes 108 may be depicted in FIG. 2 by (i) a first portion of cooling tubes 108 labeled as heated liquid line-in 210, the first portion adapted to direct (e.g., a heated portion of) the fluid toward a device positioned proximate to chassis 112’s exterior, and (ii) a second portion of cooling tubes 108 labeled as cooled liquid line-out 220, the second portion adapted to direct (e.g., a cooled portion of) the fluid back toward chassis 112 from the device positioned proximate to the exterior. Therefore, it will be appreciated that (i) heated liquid line-in 210 may provide thermal dissipator 200 with the fluid after the fluid is heated, and that (ii) the cooled liquid line-out 220 may receive the fluid, once cooled (e.g., once having transferred the heat from the fluid to the air via airflow through at least a portion of thermal dissipator 200), from traversal through thermal dissipator 200 and may provide chassis 112 with the now-cooled fluid.

Thermal dissipator 200 may (i) receive (e.g., a heated portion of) the fluid (e.g., via heated liquid line-in 210), (ii) dissipate the heat from the fluid into the air (therefore cooling the fluid), and (iii) dispense (e.g., a cooled portion of) the fluid (e.g., via cooled liquid line-out 220). For example, thermal dissipator 200 may be implemented by the above-mentioned radiator positioned proximate to chassis 112’s exterior and positioned to be in thermal communication with data processing system 100. This thermal communication may include the traversal of the fluid through alternating flow paths that may result in, for example, bidirectional thermal dissipation that contributes to the thermal management of data processing system 100.

While illustrated in FIG. 2 with a limited number of specific components, a system may include additional, fewer, and/or different components without departing from embodiments disclosed herein.

For additional information regarding thermal dissipator 200, refer to the discussion of FIG. 3 below.

Turning to FIG. 3, a diagram illustrating a thermal dissipator (e.g., 200) in accordance with an embodiment is shown. The thermal dissipator shown in FIG. 3 may provide thermal management for data processing system 100 to decrease a likelihood of negatively impacting (e.g., due to a buildup of heat) the computer implemented services to be provided by data processing system 100. For example, as previously discussed, data processing system 100 may include chassis 112 for housing a heat generating component, the liquid cooling system (e.g., discussed with regard to FIG. 1) for thermal management of data processing system 100 traversing a boundary of the chassis to facilitate flow of (e.g., the heated portion of) the fluid from the heat generating component to thermal dissipator 200.

Also as previously discussed, thermal dissipator 200 may dissipate heat from the fluid to the air flowing in the ambient environment via, for example, bidirectional thermal dissipation. To do so (e.g., facilitate the bidirectional thermal dissipation), thermal dissipator 200 may include a first set of radiators (e.g., fin 123A, fin 123C, etc.), a second set of radiators (e.g., fin 123B, a fin below fin 123A, etc.), and a set of manifolds (e.g., 212, 214A-214D, 222, etc.). Each of these is discussed below.

The set of manifolds may, for example, (i) distribute a first portion of a hot fluid (e.g., a first sub-portion of the heated portion) to the first set of radiators, (ii) distribute a second portion of the hot fluid (e.g., a second sub-portion of the heated portion) to the second set of radiators, (iii) establish a first flow of the first portion of the hot fluid in the first set of radiators in a first direction, and (iv) establish a second flow of the second portion of the hot fluid in the second set of radiators in a second direction that is different from the first direction. To provide its functionality, the set of manifolds may be implemented by, for example, manifold 214A-214D and, in some cases, divider 212 and/or combiner 222. Each of these example implementations are depicted in FIG. 3 and discussed below with regard to FIG. 3.

Manifolds 214A-214Dmay include a first pair of the manifolds (e.g., 214Aand 214C) attached to the first set of radiators (e.g., fins 123A and 123C), and a second pair of the manifolds (e.g., 214Band 214D) attached to the second set of radiators (e.g., fin 123B, etc.).

It will be appreciated that although discussed with regard to the diagram shown in FIG. 3, it will be appreciated that each pair of the manifolds may facilitate flows of the fluid into and out of any number of radiators. For example, each manifold may receive and/or distribute (e.g., direct) the first portion of the hot fluid or the second portion of the hot fluid to and/or from, respectively, any number of radiators. For example, in the diagram of FIG. 3, the set of the manifolds may be implemented by hollow, tubular, molded, structures adapted to direct liquid (e.g., the fluid). Additionally, manifolds 214A-214D, may include any number of inlets and outlets (e.g., 216A-216B and 217A-217B, mentioned further below) adapted/positioned to act as receiving ports and/or exhaust ports of the manifold to receive and/or dispense the liquid. For example, the inlets and outlets may be openings in the manifolds’ structures that allow the fluid too to be directed through each of fins 123 as discussed further below.

For example, while the first portion of the hot fluid traverses the first set of radiators, as depicted by the three arrows overlapped with, for example, fin 123C, that point toward a right of the page, a first thermal profile across the first set of radiators may be established. This then established first thermal profile may be indicated by the three arrows having lighter shading from one another as they are positioned to the right of one another (e.g., the right side from our perspective when looking into the page). This lighter shading may indicate the cooling of the first portion of the hot fluid as it is directed toward a right of the page from manifold 214A, across fin 123A, and to manifold 214C. To facilitate this directed traversal, the first pair of the manifolds may include exhaust ports such as outlet 216A and receiving ports such as inlet 217A, the first portion of the hot fluid being dispensed from manifold 214A from outlet 216A and entering manifold 214C through inlet 217A after traversing an interior of fin123A.

Additionally, for example, while the second portion of the hot fluid traverses the second set of radiators, as depicted by the three arrows overlapped with, for example, fin 123B, that point toward a left of the page, a second thermal profile across the second set of radiators may be established. This then established second thermal profile may be indicated by the three arrows having lighter shading from one another as they are positioned to the left of one another (e.g., the left side from our perspective when looking into the page). This light shading may indicate the cooling of the second portion of the hot fluid as it is directed toward a left of the page from manifold 214D to manifold 214B. To facilitate this directed traversal, the second pair of the manifolds may include exhaust ports such as outlet 216B and receiving ports such as inlet 217B, the second portion of the hot fluid being dispensed from manifold 214DC from outlet 216B, flowed along an interior of fin 123B, and entering manifold 214B through inlet 217B.

Therefore, it will be appreciated that, as shown in FIG. 3, the first thermal profile may be inverse to the second thermal profile. Consequently, due to being inverse to one another, such thermal profiles may facilitate (e.g., embody), for example, the bidirectional thermal dissipation via the alternating flow paths.

Thermal dissipator 200 may further include divider 212 and combiner 222, divider 212 and combiner 222 providing their respective functionalities when implemented by, for example, additional manifolds. These additional manifolds may, for example, (i) distribute the first and the second portions of the hot fluid to manifolds 214A and 214D, (ii) receive the first and the second portions of the hot fluid (e.g., once the fluid is cooled and dispensed from manifolds 214B and 214C), and (iii) combine the received dispensed fluid as it is received from, for example, manifolds 214B and 1214C.

For example, divider 212 may receive the (heated) fluid for thermal dissipator 200 from heated liquid line-in 210. This (heated) fluid may then, due to the functional structure of divider 212, be divided to flow through at least two flow paths, resulting in the hot fluid being divided into the first portion and the second portion of the hot fluid.

To provide its above-mentioned functionality, divider 212 may include (i) a hot fluid receiving port, and (ii) at least two hot fluid exhaust ports to flow, for example, the first portion of the hot fluid to the first pair of the manifolds and flow the second portion of the hot fluid to the second pair of the manifolds. Divider 212 may therefore receive the fluid (previously discussed with regard to FIGS. 1 and 2), once heated (e.g., depicted in FIG. 3 by dark shaded arrows) and directed through the previously discussed cooling tubes 108, from heated liquid line-in 210.

To provide its functionality of combining (i) a first portion of cooled fluid (the first portion of hot fluid once its heat has, at least in part, been dissipated) and (ii) a second portion of the cooled fluid (the second portion of hot fluid once its heat has, at least in part, been dissipated), combiner 222 may include, for example, (i) a cooled fluid exhaust port, and (ii) at least two cooled fluid receiving ports to (i) flow the first portion of the cooled fluid from the first pair of the manifolds and (ii) flow the second portion of the cooled fluid from the second pair of the manifolds. Combiner 222 may therefore provide the fluid, once cooled (e.g., as depicted in FIG. 3 by solid white arrows (e.g., unshaded arrows), to cooled liquid line-out 220.

As previously mentioned above, the first set of radiators and the second set of radiators may be implemented, for example, by fins 123. It will be appreciated that although not all labeled as fins 123A-123C are labeled, the first set of radiators and the second set of radiators may be aligned and interleaved.

Fins 123 may dissipate heat from the portions of the hot fluid respectively directed through each of fins 123, thereby cooling the portions of the hot fluid as an airflow is directed in between each of fins 123 and then provided to another one of the manifolds to be directed back towards, for example, chassis 112. To provide its functionality, fins 123 may include any number of radiators such as fins 123A-123C, these radiators facilitating thermal flow paths that are inverse to one another. For example, a radiator (e.g., each radiator) of the first portion of radiators and/or the second portion of radiators may include (i) a fluid receiving port, (ii) a fluid exhaust port, and (iii) a surface adapted to exhaust heat into an ambient environment (e.g., exhaust heat into the air of the previously mentioned airflow).

To provide its above-mentioned functionality, the radiator may further include a fluid conduit between the fluid receiving port and the fluid exhaust port to enable the hot fluid (e.g., a respective portion of the hot fluid) to traverse proximate to the surface where the thermal difference between the proximate airflow and the hot fluid is the previously discussed thermal delta on which efficiency of the bidirectional thermal dissipation is based.

Therefore, by facilitating the bidirectional thermal dissipation via thermal dissipator 200 while in thermal communication with data processing system 100, a thermal delta between (i) the traversing fluid and (ii) air within the ambient environment that flows passed (and/or in between) the radiators, may be retained within an optimal range conducive to a sufficient rate of heat dissipation. For example, if compared to prior methods using unilateral thermal dissipation (e.g., that would be depicted from just a left of the page to a right of the page rather than alternating from left-to-right to right-to-left as shown in, for example, FIG. 3), a deprecating buildup of heat may be less likely to occur in systems using bidirectional thermal dissipation.

Thus, to increase efficiency of data processing system’s thermal regulation, a rate of heat dissipation may be increased, and may therefore be more likely retained within a range of sufficient heat dissipation, by increasing thermal deltas of an operably connected thermal dissipator (200). Such a rate increase of the thermal dissipation capability of the previously discussed liquid cooling system may therefore enhance system management of data processing systems when utilized with alternating flow paths.

Any of the processes and/or components illustrated in and/or discussed with regard to FIGS. 1-3 may be implemented with and/or used in conjunction with one or more computing devices (e.g., a computing device (e.g., 100) that may be equipped with a liquid cooling system that utilizes a “bidirectional” thermal dissipator (e.g., 200) for facilitating thermal management of the system).

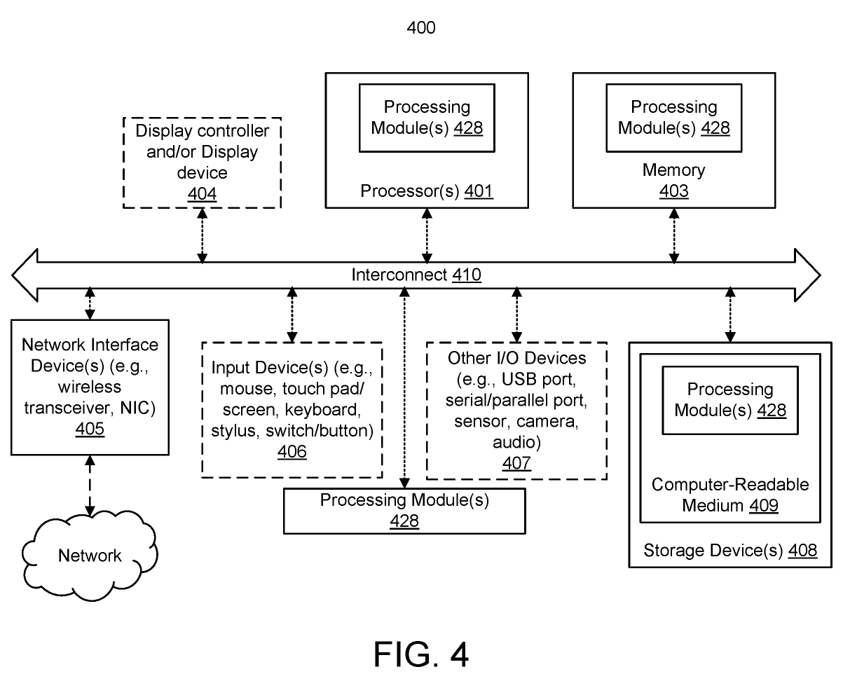

Turning to FIG. 4, a block diagram illustrating an example of a data processing system (e.g., a computing device) in accordance with an embodiment is shown. For example, system 400 may represent any of data processing systems described above performing any of the processes or methods described above. System 400 can include many different components. These components can be implemented as integrated circuits (ICs), portions thereof, discrete electronic devices, or other modules adapted to a circuit board such as a motherboard or add-in card of the computer system, or as components otherwise incorporated within a chassis of the computer system. Note also that system 400 is intended to show a high-level view of many components of the computer system. However, it is to be understood that additional components may be present in certain implementations and furthermore, different arrangement of the components shown may occur in other implementations. System 400 may represent a desktop, a laptop, a tablet, a server, a mobile phone, a media player, a personal digital assistant (PDA), a personal communicator, a gaming device, a network router or hub, a wireless access point (AP) or repeater, a set-top box, or a combination thereof. Further, while only a single machine or system is illustrated, the term “machine” or “system” shall also be taken to include any collection of machines or systems that individually or jointly execute a set (or multiple sets) of instructions to perform any one or more of the methodologies discussed herein.

In one embodiment, system 400 includes processor 401, memory 403, and devices 405-407 via a bus or an interconnect 410. Processor 401 may represent a single processor or multiple processors with a single processor core or multiple processor cores included therein. Processor 401 may represent one or more general-purpose processors such as a microprocessor, a central processing unit (CPU), or the like. More particularly, processor 401 may be a complex instruction set computing (CISC) microprocessor, reduced instruction set computing (RISC) microprocessor, very-long instruction word (VLIW) microprocessor, or processor implementing other instruction sets, or processors implementing a combination of instruction sets. Processor 401 may also be one or more special-purpose processors such as an application specific integrated circuit (ASIC), a cellular or baseband processor, a field programmable gate array (FPGA), a digital signal processor (DSP), a network processor, a graphics processor, a network processor, a communications processor, a cryptographic processor, a co-processor, an embedded processor, or any other type of logic capable of processing instructions.

Processor 401, which may be a low power multi-core processor socket such as an ultra-low voltage processor, may act as a main processing unit and central hub for communication with the various components of the system. Such processor can be implemented as a system on chip (SoC). Processor 401 is configured to execute instructions for performing the operations discussed herein. System 400 may further include a graphics interface that communicates with optional graphics subsystem 404, which may include a display controller, a graphics processor, and/or a display device.

Processor 401 may communicate with memory 403, which in one embodiment can be implemented via multiple memory devices to provide for a given amount of system memory. Memory 403 may include one or more volatile storage (or memory) devices such as random-access memory (RAM), dynamic RAM (DRAM), synchronous DRAM (SDRAM), static RAM (SRAM), or other types of storage devices. Memory 403 may store information including sequences of instructions that are executed by processor 401, or any other device. For example, executable code and/or data of a variety of operating systems, device drivers, firmware (e.g., input output basic system or BIOS), and/or applications can be loaded in memory 403 and executed by processor 401. An operating system can be any kind of operating systems, such as, for example, Windows® operating system from Microsoft®, Mac OS®/iOS® from Apple, Android® from Google®, Linux®, Unix®, or other real-time or embedded operating systems such as VxWorks.

System 400 may further include IO devices such as devices (e.g., 405, 406, 407, 408) including network interface device(s) 405, optional input device(s) 406, and other optional IO device(s) 407. Network interface device(s) 405 may include a wireless transceiver and/or a network interface card (NIC). The wireless transceiver may be a Wi-Fi transceiver, an infrared transceiver, a Bluetooth transceiver, a WiMAX transceiver, a wireless cellular telephony transceiver, a satellite transceiver (e.g., a global positioning system (GPS) transceiver), or other radio frequency (RF) transceivers, or a combination thereof. The NIC may be an Ethernet card.

Input device(s) 406 may include a mouse, a touch pad, a touch sensitive screen (which may be integrated with a display device of optional graphics subsystem 404), a pointer device such as a stylus, and/or a keyboard (e.g., physical keyboard or a virtual keyboard displayed as part of a touch sensitive screen). For example, input device(s) 406 may include a touch screen controller coupled to a touch screen. The touch screen and touch screen controller can, for example, detect contact and movement or break thereof using any of a plurality of touch sensitivity technologies, including but not limited to capacitive, resistive, infrared, and surface acoustic wave technologies, as well as other proximity sensor arrays or other elements for determining one or more points of contact with the touch screen.

IO devices 407 may include an audio device. An audio device may include a speaker and/or a microphone to facilitate voice-enabled functions, such as voice recognition, voice replication, digital recording, and/or telephony functions. Other IO devices 407 may further include universal serial bus (USB) port(s), parallel port(s), serial port(s), a printer, a network interface, a bus bridge (e.g., a PCI-PCI bridge), sensor(s) (e.g., a motion sensor such as an accelerometer, gyroscope, a magnetometer, a light sensor, compass, a proximity sensor, etc.), or a combination thereof. IO device(s) 407 may further include an imaging processing subsystem (e.g., a camera), which may include an optical sensor, such as a charged coupled device (CCD) or a complementary metal-oxide semiconductor (CMOS) optical sensor, utilized to facilitate camera functions, such as recording photographs and video clips. Certain sensors may be coupled to interconnect 410 via a sensor hub (not shown), while other devices such as an embedded controller (not shown) may control a keyboard or thermal sensor, dependent upon the specific configuration or design of system 400.

To provide for persistent storage of information such as data, applications, one or more operating systems and so forth, a mass storage (not shown) may also couple to processor 401. In various embodiments, to enable a thinner and lighter system design as well as to improve system responsiveness, this mass storage may be implemented via a solid-state device (SSD). However, in other embodiments, the mass storage may primarily be implemented using a hard disk drive (HDD) with a smaller amount of SSD storage to act as an SSD cache to enable non-volatile storage of context state and other such information during power down events so that a fast power up can occur on re-initiation of system activities. Also, a flash device may be coupled to processor 401, e.g., via a serial peripheral interface (SPI). This flash device may provide for non-volatile storage of system software, including a basic input/output software (BIOS) as well as other firmware of the system.

Storage device 408 may include computer-readable storage medium 409 (also known as a machine-readable storage medium or a computer-readable medium) on which is stored one or more sets of instructions or software (e.g., processing module, unit, and/or processing module/unit/logic 428) embodying any one or more of the methodologies or functions described herein. Processing module/unit/logic 428 may represent any of the components described above. Processing module/unit/logic 428 may also reside, completely or at least partially, within memory 403 and/or within processor 401 during execution thereof by system 400, memory 403 and processor 401 also constituting machine-accessible storage media. Processing module/unit/logic 428 may further be transmitted or received over a network via network interface device(s) 405.

Computer-readable storage medium 409 may also be used to store some software functionalities described above persistently. While computer-readable storage medium 409 is shown in an exemplary embodiment to be a single medium, the term “computer-readable storage medium” should be taken to include a single medium or multiple media (e.g., a centralized or distributed database, and/or associated caches and servers) that store the one or more sets of instructions. The terms “computer-readable storage medium” shall also be taken to include any medium that is capable of storing or encoding a set of instructions for execution by the machine and that cause the machine to perform any one or more of the methodologies of embodiments disclosed herein. The term “computer-readable storage medium” shall accordingly be taken to include, but not be limited to, solid-state memories, and optical and magnetic media, or any other non-transitory machine-readable medium.

Processing module/unit/logic 428, components and other features described herein can be implemented as discrete hardware components or integrated in the functionality of hardware components such as ASICS, FPGAs, DSPs or similar devices. In addition, processing module/unit/logic 428 can be implemented as firmware or functional circuitry within hardware devices. Further, processing module/unit/logic 428 can be implemented in any combination hardware devices and software components.

Note that while system 400 is illustrated with various components of a data processing system, it is not intended to represent any particular architecture or manner of interconnecting the components as such details are not germane to embodiments disclosed herein. It will also be appreciated that network computers, handheld computers, mobile phones, servers, and/or other data processing systems which have fewer components, or (perhaps) more components may also be used with embodiments disclosed herein.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and (generally) conceived to be a self-consistent sequence of operations leading to a desired result. The operations are those requiring physical manipulations of physical quantities.

It should be borne in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as those set forth in the claims below, refer to the action and processes of a computer system, or similar electronic computing device, that manipulates and transforms data represented as physical (electronic) quantities within the computer system’s registers and memories into other data similarly represented as physical quantities within the computer system memories or registers or other such information storage, transmission or display devices.

Embodiments disclosed herein also relate to an apparatus for performing the operations herein. Such a computer program is stored in a non-transitory computer readable medium. A non-transitory machine-readable medium includes any mechanism for storing information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices).

The processes or methods depicted in the preceding figures may be performed by processing logic that comprises hardware (e.g., circuitry, dedicated logic, etc.), software (e.g., embodied on a non-transitory computer readable medium), or a combination of both. Although the processes or methods are described above in terms of some sequential operations, it should be appreciated that some of the operations described may be performed in a different order. Moreover, some operations may be performed in parallel rather than sequentially.

Embodiments disclosed herein are not described with reference to any particular programming language. It will be appreciated that a variety of programming languages may be used to implement the teachings of embodiments disclosed herein.

In the foregoing specification, embodiments have been described with reference to specific exemplary embodiments thereof. It will be evident that various modifications may be made thereto without departing from the broader spirit and scope of the embodiments disclosed herein as set forth in the following claims. The specification and drawings are, accordingly, to be regarded in an illustrative sense rather than a restrictive sense.

What is claimed is:

1. A data processing system comprising:
a heat generating component;
a liquid cooling system to cool the heat generating component; and
a thermal dissipator to dissipate heat in the liquid cooling system, the thermal dissipator comprising:
a first set of radiators;
a second set of radiators; and
a set of manifolds adapted to:
distribute a first portion of a hot fluid to the first set of radiators;
distribute a second portion of the hot fluid to the second set of radiators;
establish a first flow of the first portion of the hot fluid in the first set of radiators in a first direction; and
establish a second flow of the second portion of the hot fluid in the second set of radiators in a second direction that is different from the first direction.

2. The data processing system of claim 1, wherein the first set of radiators and the second set of radiators are aligned.

3. The data processing system of claim 2, wherein the first set of radiators and the second set of radiators are interleaved.

4. The data processing system of claim 3, wherein a radiator of the first set of radiators comprises:
a fluid receiving port;
a fluid exhaust port; and
a surface adapted to exhaust heat into an ambient environment.

5. The data processing system of claim 4, wherein the radiator further comprises:
a fluid conduit between the fluid receiving port and the fluid exhaust port to enable the hot fluid to traverse proximate to the surface.

6. The data processing system of claim 3, wherein the set of the manifolds comprises:
a first pair of the manifolds attached to the first set of radiators; and
a second pair of the manifolds attached to the second set of radiators.

7. The data processing system of claim 6, wherein the thermal dissipator further comprises:
a fluid divider to divide the hot fluid into the first portion of the hot fluid and the second portion of the hot fluid.

8. The data processing system of claim 7, wherein the fluid divider comprises:
a hot fluid receiving port; and
at least two hot fluid exhaust ports to flow the first portion of the hot fluid to the first pair of the manifolds and flow the second portion of the hot fluid to the second pair of the manifolds.

9. The data processing system of claim 6, wherein the thermal dissipator further comprises:
a fluid combiner to combine a first portion of cooled fluid and a second portion of the cooled fluid.

10. The data processing system of claim 9, wherein the fluid combiner comprises:
a cooled fluid exhaust port; and
at least two cooled fluid receiving ports to flow the first portion of the cooled fluid from the first pair of the manifolds and flow the second portion of the cooled fluid from the second pair of the manifolds.

11. The data processing system of claim 1, wherein while the first portion of the hot fluid traverses the first set of radiators, a first thermal profile across the first set of radiators is established.

12. The data processing system of claim 11, wherein while the second portion of the hot fluid traverses the second set of radiators, a second thermal profile across the second set of radiators is established.

13. The data processing system of claim 12, wherein the first thermal profile is inverse to the second thermal profile.

14. The data processing system of claim 1, further comprising:
a chassis for housing the heat generating component,
wherein the liquid cooling system traverses a boundary of the chassis to facilitate flow of the hot fluid from the heat generating component to the thermal dissipator.

15. A liquid cooled chassis, comprising:
a liquid cooling system to cool a heat generating component; and
a thermal dissipator to dissipate heat in the liquid cooling system, the thermal dissipator comprising:
a first set of radiators;
a second set of radiators; and
a set of manifolds adapted to:
distribute a first portion of a hot fluid to the first set of radiators;
distribute a second portion of the hot fluid to the second set of radiators;
establish a first flow of the first portion of the hot fluid in the first set of radiators in a first direction; and
establish a second flow of the second portion of the hot fluid in the second set of radiators in a second direction that is different from the first direction.

16. The liquid cooled chassis of claim 15, wherein while the first portion of the hot fluid traverses the first set of radiators, a first thermal profile across the first set of radiators is established.

17. The liquid cooled chassis of claim 16, wherein while the second portion of the hot fluid traverses the second set of radiators, a second thermal profile across the second set of radiators is established, the first thermal profile being inverse to the second thermal profile.

18. A rack system, comprising:
a rack; and
a data processing system to be housed in the rack, the data processing system comprising:
a heat generating component;
a liquid cooling system to cool the heat generating component; and
a thermal dissipator to dissipate heat in the liquid cooling system, the thermal dissipator comprising:
a first set of radiators;
a second set of radiators; and
a set of manifolds adapted to:
distribute a first portion of a hot fluid to the first set of radiators;
distribute a second portion of the hot fluid to the second set of radiators;
establish a first flow of the first portion of the hot fluid in the first set of radiators in a first direction; and
establish a second flow of the second portion of the hot fluid in the second set of radiators in a second direction that is different from the first direction.

19. The rack system of claim 18, wherein while the first portion of the hot fluid traverses the first set of radiators, a first thermal profile across the first set of radiators is established.

20. The rack system of claim 19, wherein while the second portion of the hot fluid traverses the second set of radiators, a second thermal profile across the second set of radiators is established, the first thermal profile being inverse to the second thermal profile.
